(19) United States
(12) Patent Application Publication
(10) Pub. No.: US 2014/0197426 A1
(43) Pub. Date: Jul. 17, 2014

(54) LIGHT EMITTING DIODE CHIP STRUCTURE AND LIGHT EMITTING DIODE ELEMENT

(71) Applicant: LEXTAR ELECTRONICS CORPORATION, Hsinchu (TW)

(72) Inventors: Fu-Shin Chen, Xinfeng Township (TW); Li-Cheng Yang, Zhongli City (TW); Yu-Chun Lee, Taichung City (TW)

(73) Assignee: LEXTAR ELECTRONICS CORPORATION, Hsinchu (TW)

(21) Appl. No.: 13/856,872

(22) Filed: Apr. 4, 2013

(30) Foreign Application Priority Data
Jan. 16, 2013 (TW) 102101652

(51) Int. Cl. H01L 27/15

(52) U.S. Cl. CPC H01L 27/15
USPC 257/88

(57) ABSTRACT

A light emitting diode chip structure includes a substrate, a mesa type light emitting diode structure, and an electroluminescent layer. The mesa type light emitting diode structure includes a first semiconductor layer, a light emitting layer, and a second semiconductor layer. The mesa type light emitting diode structure is formed on the substrate. The first semiconductor layer is formed on the substrate. The light emitting layer is formed on a portion of the first semiconductor layer, and a portion of the first semiconductor layer is uncovered. The second semiconductor layer is formed on the light emitting layer. The electroluminescent layer is formed on the second semiconductor layer. Furthermore, a light emitting diode element is also disclosed herein.

### RELATED APPLICATIONS

This application claims priority to Taiwan Application Serial Number 102101652, filed Jan. 16, 2013, which is herein incorporated by reference.

### BACKGROUND

1. Field of Invention

The present invention relates to a semiconductor device. More particularly, the present invention relates to a light emitting diode element and a light emitting diode chip structure.

2. Description of Related Art

Since Japan successfully produced a high-brightness blue diode with volume production in 1994, the application range of LED has been increased greatly. Moreover, with the improvement of LED production yield, the unit manufacturing cost has been decreased, and the demand on the light emitting diode has been constantly increased.

For characteristics, the light emitting diode (LED) is one type of semiconductor element. Based on the characteristics of the LED, such as small size, long service life and low power consumption, the LED has already been applied in a 3C product indicator, a display device and the like.

However, a general light emitting diode chip only has a single light emitting angle, resulting in a limited irradiation range, so that the application range of the light emitting diode chip is limited. It can be seen that the aforesaid existing way still has inconvenience and defects and needs to be improved. In order to solve the aforesaid problems, a solution way is sought with great effort in the relevant fields. However, developing a proper solution scheme is still a failure all the time.

### SUMMARY

A technical aspect of the present invention relates to a light emitting diode chip structure, which includes a substrate, a mesa type light emitting diode structure and an electroluminescent layer. Furthermore, the mesa type light emitting diode structure includes a first semiconductor layer, a light emitting layer and a second semiconductor layer. Structurally, the mesa type light emitting diode structure is formed on the substrate. Furthermore, the first semiconductor layer is disposed on the substrate, the light emitting layer is disposed on a portion of the first semiconductor layer, and a portion of the first semiconductor layer is uncovered. The second semiconductor layer is disposed on the light emitting layer, and the electroluminescent layer is disposed on the second semiconductor layer.

Another aspect of the present invention relates to a light emitting diode element, which includes a light emitting diode chip and a wavelength transformation substance. The light emitting diode chip is configured for emitting a first light with a light wavelength λ1. The wavelength transformation substance is configured for transforming the first light with the light wavelength λ1 into a second light with a light wavelength λ2 after the wavelength transformation substance is irradiated by the first light with the light wavelength λ1. Furthermore, the light emitting diode chip includes a substrate, a mesa type light emitting diode structure and an electroluminescent layer. The mesa type light emitting diode structure is formed on the substrate. The electroluminescent layer is disposed on the second luminescent layer. Additionally, the mesa type light emitting diode structure includes a first semiconductor layer, a light emitting layer and a second semiconductor layer. The first semiconductor layer is disposed on the substrate. The light emitting layer is disposed on a portion of the first semiconductor layer, and a portion of the first semiconductor layer is uncovered. The second semiconductor layer is disposed on the light emitting layer.

Therefore, according to the technical contents of the present invention, the embodiment of the present invention provides the light emitting diode element and the light emitting diode chip structure thereof to solve the problem that the general light emitting diode chip only has a single light emitting angle, resulting in the limited irradiation range, so that the application range of the light emitting diode chip is limited.

### BRIEF DESCRIPTION OF THE DRAWINGS

In order to make the following as well as other aspects, features, advantages, and embodiments of the present invention more apparent, the accompanying drawings are described as follows:

FIG. 1 illustrates a schematic diagram of a light emitting diode chip structure according to an embodiment of the present invention;

FIG. 2A illustrates a schematic shape diagram of light emitted by a light emitting diode chip according to the prior art; and FIG. 2B illustrates a schematic shape diagram of light emitted by a light emitting diode chip according to an embodiment of the present invention;

FIG. 3 illustrates a schematic diagram of a light emitting diode chip structure according to another embodiment of the present invention;

FIG. 4A illustrates a schematic light transmittance diagram of an electroluminescent layer of a light emitting diode chip structure according to an embodiment of the present invention; and FIG. 4B illustrates a schematic light transmittance diagram of the electroluminescent layer of the light emitting diode chip structure according to another embodiment of the present invention;

FIG. 5A illustrates a schematic emergent light path diagram of the light emitting diode chip structure according to an embodiment of the present invention; and FIG. 5B illustrates a schematic shape diagram of light emitted by the light emitting diode chip structure according to another embodiment of the present invention;

FIG. 6A illustrates a schematic emergent light path diagram of the light emitting diode chip structure according to an embodiment of the present invention; and FIG. 6B illustrates a schematic shape diagram of the light emitting diode chip structure according another embodiment of the present invention;

FIGS. 7A-7E illustrate schematic diagrams of corresponding relationships between the voltage applied onto the electroluminescent layer and the light shape according to an embodiment of the present invention; and

FIG. 8 illustrates a schematic diagram of a light emitting diode chip structure according to yet another embodiment of the present invention.

### DETAILED DESCRIPTION

In order to make the description of the present invention more detailed and more comprehensive, various embodiments are described below with reference to the accompanying drawings. The same reference numbers are used in the drawings to refer to the same or like elements. However, these embodiments are not intended to limit the present invention. The description of structure operation does not mean to limit its implementation order. Any device with equivalent functions that is produced from a structure formed by recombination of elements shall fall within the scope of the present invention.

The drawings are only illustrative and are not made according to the original size. Additionally, well-known elements and steps are not described in the embodiments to avoid causing unnecessary limitations to the invention.

Additionally, the phrases “coupling” or “connecting” used herein both refer to that two or more elements physically or electrically contact with each other directly or indirectly, or refer to that two or more elements inter-operate or interact with each other.

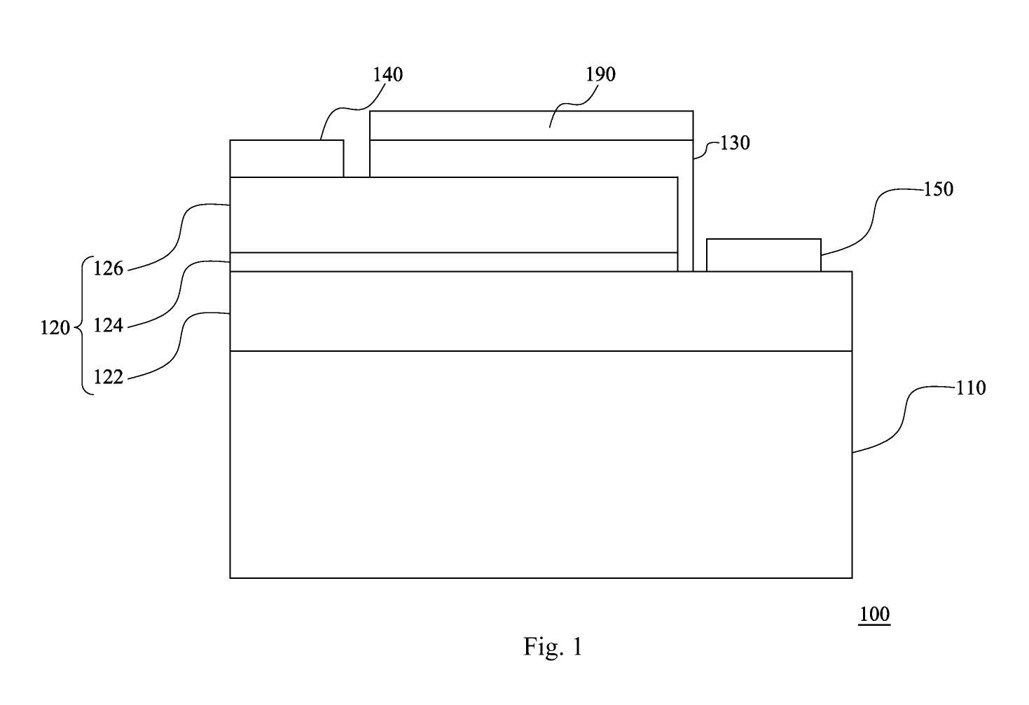

FIG. 1 illustrates a schematic diagram of a light emitting diode chip structure according to an embodiment of the present invention. As shown in the figure, the light emitting diode chip structure 100 includes a substrate 110, a mesa type light emitting diode structure 120 and an electroluminescent layer 130. Furthermore, the mesa type light emitting diode structure 120 includes a first semiconductor layer 122, a light emitting layer 124 and a second semiconductor layer 126.

Structurally, the mesa type light emitting diode structure 120 is formed on the substrate 110. Furthermore, the first semiconductor layer 122 of the mesa type light emitting diode structure 120 is disposed on the substrate 110. The light emitting layer 124 of the mesa type light emitting diode structure 120 is disposed on a portion of the first semiconductor layer 122, and a portion of the first semiconductor layer 122 is uncovered. However, the present invention is not limited in this regard. In other embodiments, alternatively the light emitting layer 124 may completely cover the first semiconductor layer 122. For the implementation of the present invention, the partial coverage or the full coverage should be selectively adopted according to actual demands. In addition, the second semiconductor layer 126 is disposed on the light emitting layer 124, while the electroluminescent layer 130 is disposed on the second semiconductor layer 126. However, the present invention is not limited to the structure as shown in FIG. 1. The structure shown in FIG. 1 is only used for exemplarily illustrating one embodiment of the present invention. Various modifications and variations made to the structure shown in FIG. 1 without departing from the spirit of the present invention fall in the scope of the present invention.

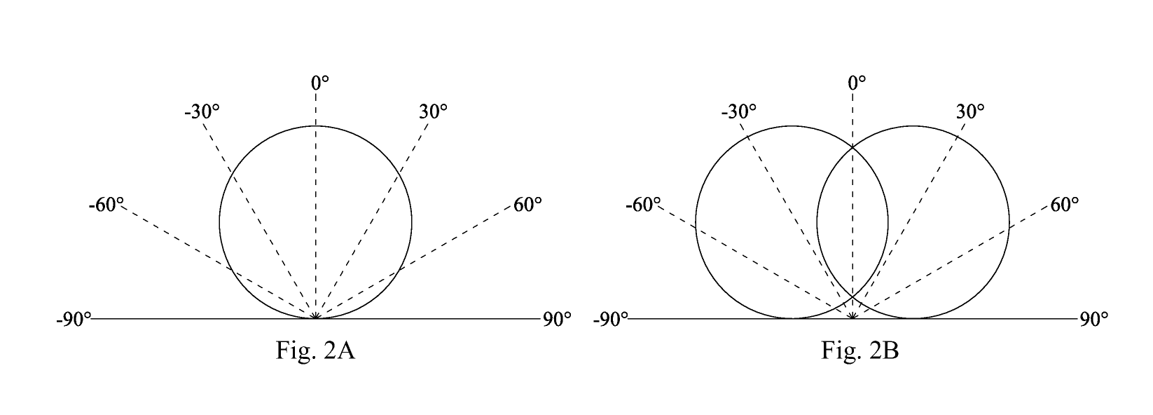

In order to make the effect of the light emitting diode chip structure 100 of the embodiment of the present invention easier to be understood, the present invention is exemplarily illustrated with reference to FIGS. 2A and 2B. FIG. 2A illustrates a schematic shape diagram of light emitted by a light emitting diode chip according to the prior art; and FIG. 2B illustrates a schematic shape diagram of light emitted by a light emitting diode chip according to an embodiment of the present invention.

As shown in FIG. 2A, a general light emitting diode chip only has one light emitting angle, so that the irradiation range is limited. However, with the adoption of the structure shown in FIG. 1 of the embodiment of the present invention, at least the electroluminescent layer 130 is added in comparison with the general light emitting diode chip. Via the electroluminescent layer 130, the light emitted from the mesa type light emitting diode structure 120 can be adjusted and controlled. As a result, the shape of the light emitted from the mesa type light emitting diode structure 120 is further changed. Therefore, the entire light emitting diode chip structure 100 is enabled to have at least two light emitting angles as shown in FIG. 2B. Accordingly, in comparison with the general light emitting diode chip only having the single light emitting angle, the light emitting diode chip structure 100 has a wider irradiation range, so that the application range thereof is expanded.

In implementation of the invention, the substrate 110 may be a sapphire substrate, a SiC substrate and the like. The first semiconductor layer 122 may be an N type semiconductor layer, and accordingly the second semiconductor layer 126 may be a P type semiconductor layer. In particular, the first semiconductor layer 122 may be an N type gallium nitride (GaN) semiconductor layer, and the second semiconductor layer 126 may be a P type GaN semiconductor layer. The light emitting layer may be a multiple quantum well (MQW). However, the material of layer structures of the present invention is not limited to the aforesaid materials and that of the present invention is only used for exemplarily illustrating one implementation of the present invention. Those skilled in the art can selectively adopt an appropriate material to manufacture the layer structures of the present invention according to the actual demands.

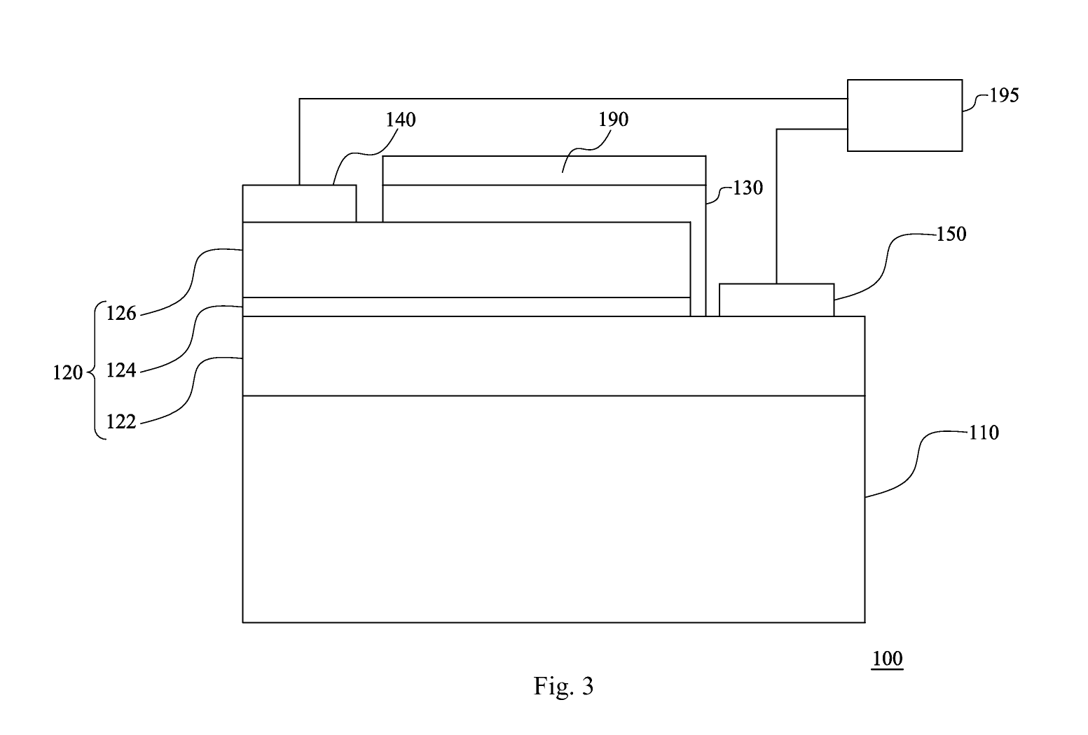

A method for adjusting and controlling the light emitted from the mesa type light emitting diode structure 120 through the electroluminescent layer 130 is described in details with reference to FIG. 3 as follows. When being implemented, the light emitting diode chip structure 100 of the embodiment of the present invention may include a first electrode 140 and a second electrode 150. Structurally, the first electrode 140 and the second electrode 150 are disposed on the first semiconductor layer 122 and the second semiconductor layer 126 respectively. An external power supplier 195 may be electrically coupled with the first electrode 140 and the second electrode 150 respectively so as to output the variable first voltage. Moreover, the variable first voltage is applied between the first semiconductor 122 and the second semiconductor layer 126 through the first electrode 140 and the second electrode 150. In addition, since the electroluminescent layer 130 is connected in series with the first semiconductor layer 122 and the second semiconductor layer 126, the variable first voltage is applied onto the electroluminescent layer 130. In such a way, the light transmittance and the light reflectance of the electroluminescent layer 130 may be changed based on the change of the aforesaid variable first voltage applied between the first semiconductor 122 and the second semiconductor layer 126.

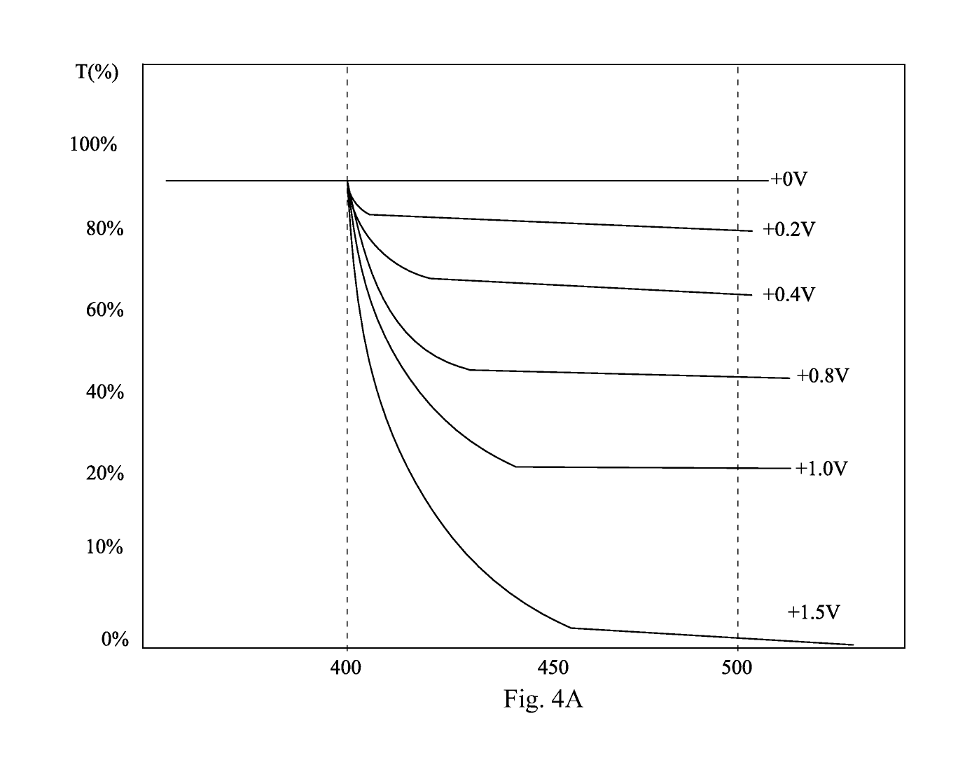

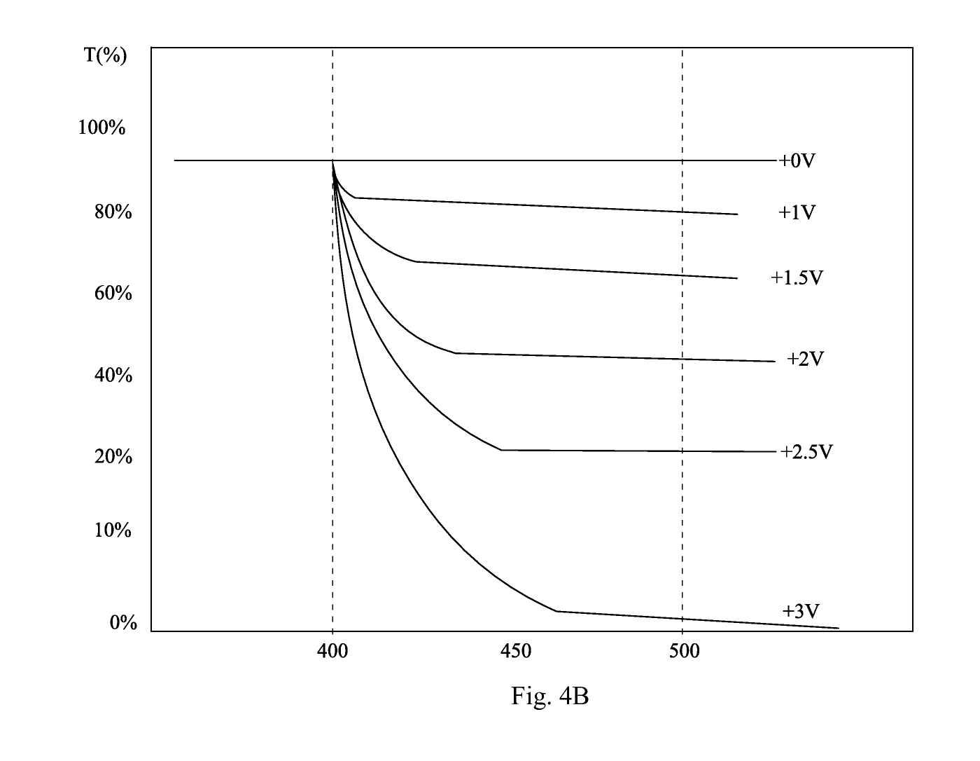

The light transmittance of the aforesaid electroluminescent layer 130 is illustrated in FIG. 4A. Herein, the electroluminescent layer 130 is practiced exemplarily by adopting TiO₂. It can be seen from curves in the figure that when the variable first voltage applied onto the electroluminescent layer 130 is gradually increased, the light transmittance (T (%)) is gradually decreased. On the contrary, when the variable first voltage is gradually decreased, the light transmittance (T (%)) is gradually increased. However, the change of the light reflectance is contrary to that of the light transmittance. The aforesaid changes of the light transmittance and the light reflectance of the electroluminescent layer 130 cause change of the shape of the light emitted by the mesa type light emitting diode structure 120. In addition, referring to FIG. 4B, it is a schematic light transmittance diagram of the electroluminescent layer 130 when the electroluminescent layer 130 is practiced by adopting NiOₓ. It can be seen from FIGS. 4A and 4B that, when the electroluminescent layer 130 is practiced by adopting NiOₓ, the voltage required to be provided to the electroluminescent layer 130 for the decrease of the light transmittance is higher in comparison with the electroluminescent layer 130 practiced by adopting NiOₓ.

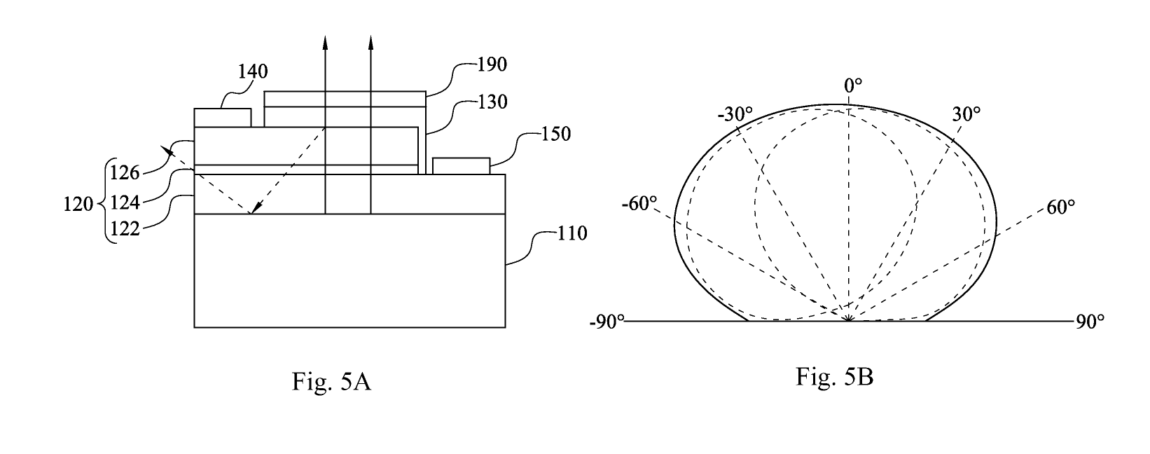

Herein, an embodiment is taken as an example to illustrate the corresponding relationship between the light transmittance and the shape of the light. Detailed descriptions are as follows. First referring to FIG. 4A, when the variable first voltage applied onto the electroluminescent layer 130 is about 0.8 V, the light transmittance is about 50%. At this moment, the electroluminescent 130 is subjected to a semi-transmittance mode, while the light emitted from the mesa type light emitting diode structure 120 is shown in FIG. 5A. A part of the light directly passes through the electroluminescent layer 130, and the other parts of light is reflected by the electroluminescent layer 130 and comes out from the side face of the mesa type light emitting diode structure 120. At this moment, the shape diagram of overall light of the light emitting diode chip structure 100 is shown in FIG. 5B. Herein, it should be noted that the black full line part is the total angle obtained by summing light emitting angles of the black spotted line parts.

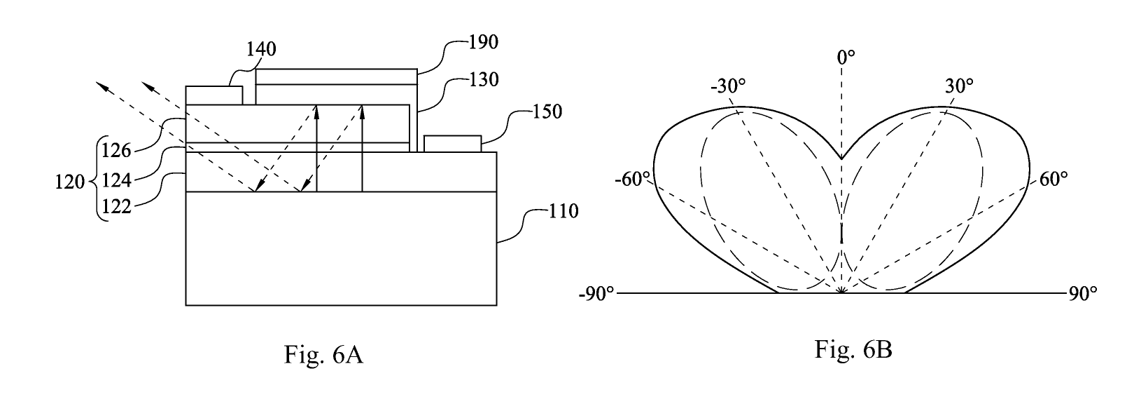

In addition, another embodiment is taken as an example to illustrate the corresponding relationship between the light transmittance and the shape of the light, and detailed descriptions thereof are as follows. First, referring to FIG. 4A, when the variable first voltage applied onto the electroluminescent layer 130 is greater than about 1.5 V, the light transmittance of the electroluminescent layer 130 is close to 0%. At this moment, the electroluminescent layer 130 is subjected to a reflection mode, and the light emitted by the mesa type light emitting diode structure 120 is shown in FIG. 6A, almost all of which is reflected by the electroluminescent layer 130, and comes out from the side face of the mesa type light emitting diode structure 120. At this moment, the shape diagram of overall lights of the light emitting diode chip structure 100 is shown in FIG. 6B. Similar to FIG. 5B, in FIG. 6B the black full line part is the total angle obtained by summing the light emitting angles of the black spotted line part.

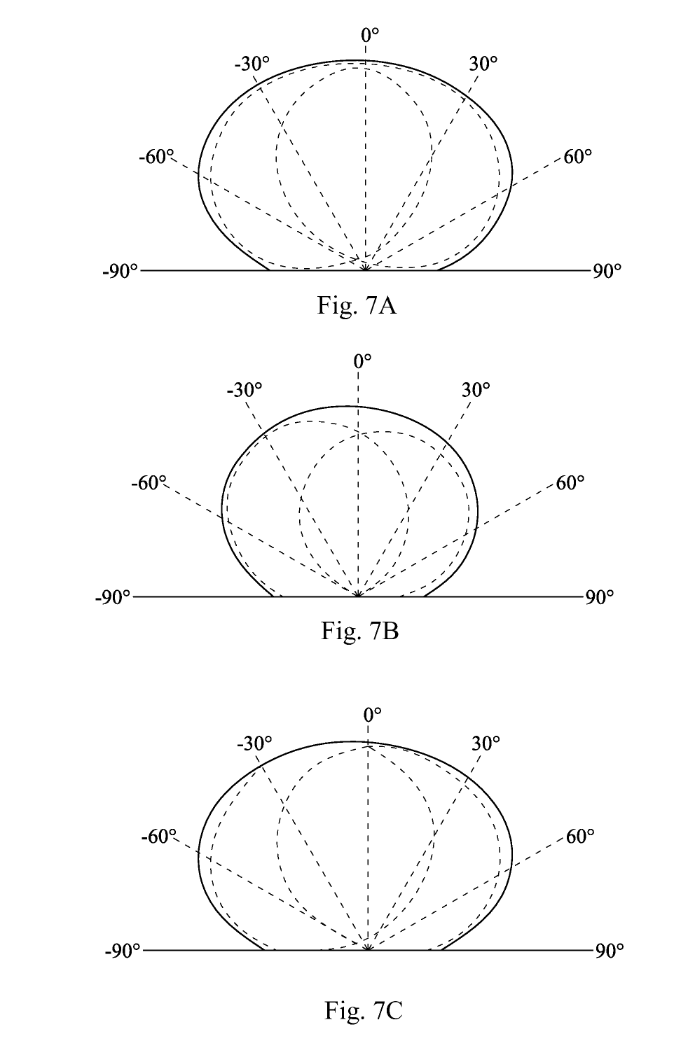

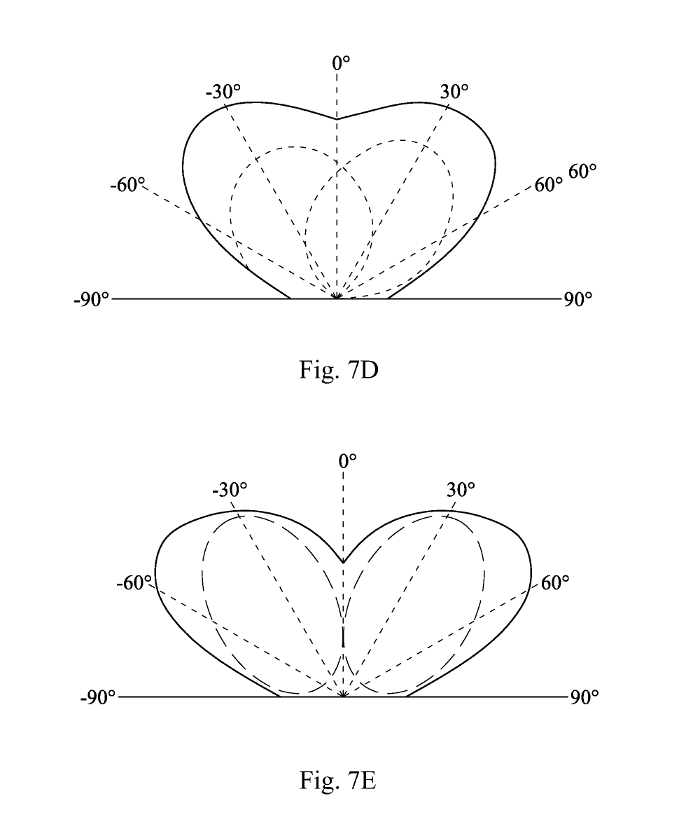

In addition, in order to make the corresponding relationship between the voltage applied onto the electroluminescent layer 130 and the shape of the light easier to be understood, the shape of the light generated when various voltages are applied onto the electroluminescent layer 130 is illustrated in the following. Herein, the electroluminescent layer 130 is practiced exemplarily by adopting TiO₂. However, the present invention is not limited in this regard. As shown in FIGS. 7A-7E, the schematic shape diagrams of the lights generated from the mesa type light emitting diode structure 120 when the voltages 0.2 V, 0.4 V, 0.8 V, 1.0 V and 1.5 V are applied sequentially onto the electroluminescent layer 130. Similar to FIG. 5B, the black full line parts of FIGS. 7A-7E are the total angle obtained by summing the light emitting angles of the integral black spotted line part.

It can be seen from the aforesaid embodiment the shape of the light emitted by the mesa type light emitting diode structure 120 can be adjusted and controlled by controlling the voltage applied onto the electroluminescent layer 130. For example, when needing more intensive light, a user may apply 0.2 V voltage onto the electroluminescent layer 130 through the external power supplier 195, so that the mesa type light emitting diode structure 120 generates the shape of the light shown in FIG. 7A. When needing a light with a wide coverage range, the user may apply 1.5 V voltage onto the electroluminescent layer 130 through the external power supplier 195, so that the mesa type light emitting diode structure 120 generates the shape of the light shown in FIG. 7E. However, the aforesaid embodiments are not used for limiting the present invention, and are only used for exemplarily illustrating one implementation of the present invention. Those skilled in the art can selectively control the voltage according to the actual demands, so that the shape of the light emitted by the mesa type light emitting diode structure 120 can be controlled.

In an embodiment of the present invention, referring to FIG. 3, the electroluminescent layer 130 further covers the second semiconductor layer 126, the light emitting layer 124 and the first semiconductor layer 122 which are disposed on the side face of the mesa type light emitting diode structure 120. In such a way, when the power supplier 195 outputs the variable first voltage and the variable first voltage is applied between the first semiconductor layer 122 and the second semiconductor layer 126 through the first electrode 140 and the second electrode 150, since the electroluminescent layer 130 is connected in series with the first semiconductor layer 122 and the second semiconductor layer 126, the variable first voltage is enabled to be applied onto the electroluminescent layer 130.

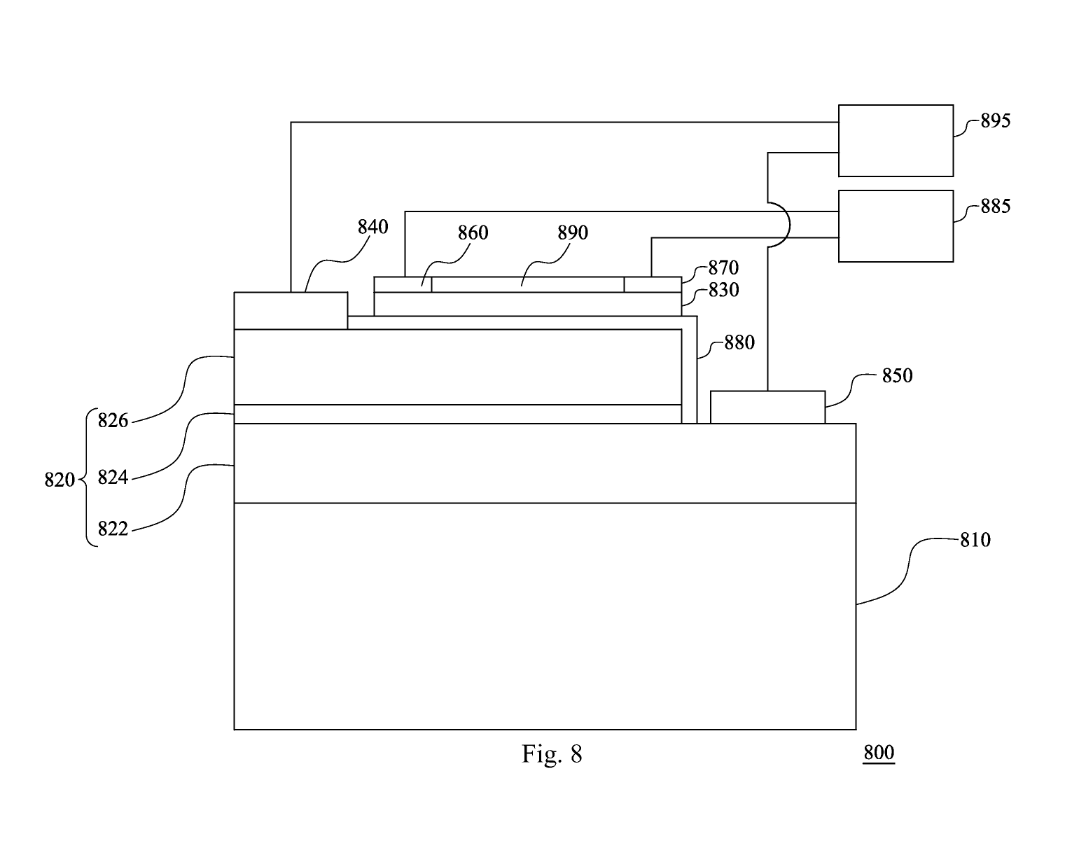

In another embodiment of the present invention, referring to FIG. 8, the difference between FIGS. 8 and 3 lies in that an insulating layer 880 is further included between the electroluminescent layer 830 and the second semiconductor layer 826 of the light emitting diode chip structure 800. In addition, the light emitting diode chip structure 800 further includes a third electrode 860 and a fourth electrode 870. In an embodiment, the light emitting diode chip structure 800 further includes a power supplier 895, which is coupled to the first electrode 840 and the second electrode 850. The power supplier 895 can output the variable first voltage. The variable first voltage is applied onto the electroluminescent layer 830 through the third electrode 860 and the fourth electrode 870.

Similarly, as shown in FIG. 8, the variable first voltage is converted to the variable second voltage through a variable resistor 885. Moreover, the variable second voltage is applied onto the electroluminescent layer 830 between the third electrode 860 and the fourth electrode 870. In this embodiment, the power supplier 895 and the variable resistor 885 can output the variable first voltage and the variable second voltage respectively. The variable first voltage and the variable second voltage are applied onto the mesa type light emitting diode structure 820 and the electroluminescent layer 830 through the first electrode 840, the second electrode 850, the third electrode 860 and the fourth electrode 870. As such, the mesa type light emitting diode structure 820 and the electroluminescent layer 830 may be caused to be controlled respectively. In such a way, the light emitting brightness and the light shape of the light emitting diode chip structure 800 are provided with more collocations. Therefore, the application range of the light emitting diode chip structure 800 is further expanded.

Moreover, the light emitting diode chip structures 100 and 800 of FIGS. 3 and 8 emit an emergent first light with a light wavelength λ1 respectively, and the light emitting diode chip structures 100 and 800 include the wavelength transformation substances 190 and 890 respectively. After the wavelength transformation substances are irradiated by the first light with the light wavelength λ1, the first light can be transformed into a second light with a light wavelength λ2. The wavelength transformation substances 190 and 890 are disposed on the electroluminescent layers 130 and 830 respectively. Moreover, the wavelength transformation substances 190 and 890 form a light emitting diode element respectively with the light emitting diode chip structures 100 and 800. In another embodiment, the wavelength λ1 of the emergent light of the light emitting diode chip structures 100 and 800 is within the wavelength range of ultraviolet light or visible light. In implementation of the present invention, the wavelength transformation substances 190 and 890 may be selected from the group consisting of fluorescent powder, pigment, paint and a combination thereof, but the present invention is not limited to these. Those skilled in the art can selectively adopt other materials capable of transforming the wavelength as the wavelength transformation substances according to the actual demands.

It can be seen from the embodiments of the present invention, the present invention has the following advantages in application. The embodiment of the present invention provides the light emitting diode element and the light emitting diode chip structure thereof to solve the problem that the general light emitting diode chip only has the single light emitting angle, resulting in the limited irradiation range, so that the application range of the light emitting diode chip is limited.

Although the present invention has been disclosed with reference to the above embodiments, these embodiments are not intended to limit the present invention. It will be apparent to those skilled in the art that various modifications and variations can be made without departing from the scope or spirit of the present invention. Therefore, the scope of the present invention shall be defined by the appended claims.

What is claimed is:

1. A light emitting diode chip structure, comprising:
a substrate;
a mesa type light emitting diode structure, formed on the substrate, comprising:
a first semiconductor layer disposed on the substrate;
a light emitting layer disposed on a portion of the first semiconductor layer, wherein a portion of the first semiconductor layer is uncovered; and
a second semiconductor layer disposed on the light emitting layer; and
an electroluminescent layer disposed on the second luminescent layer.

2. The light emitting diode chip structure according to claim 1, wherein the light transmittance and the light reflectance of the electroluminescent layer are changed based on the change of a variable voltage applied onto the electroluminescent layer.

3. The light emitting diode chip structure according to claim 2, wherein when the variable voltage applied onto the electroluminescent layer is gradually increased or decreased, the light transmittance is gradually decreased or increased, but the change of the light reflectance is contrary to that of the light transmittance.

4. The light emitting diode chip structure according to claim 3, further comprising a first electrode and a second electrode, which are respectively disposed on the first semiconductor layer and the second semiconductor layer, so that a variable first voltage is applied between the first semiconductor layer and the second semiconductor layer through the first electrode and the second electrode.

5. The light emitting diode chip structure according to claim 4, wherein since the electroluminescent layer is connected in series with the first semiconductor layer and the second semiconductor layer such that the variable first voltage is applied onto the electroluminescent layer.

6. The light emitting diode chip structure according to claim 4, further comprising an insulating layer, wherein the insulating layer is located between the second semiconductor layer and the electroluminescent layer, and the light emitting diode chip structure further comprises a third electrode and a fourth electrode which are disposed on the electroluminescent layer.

7. The light emitting diode chip structure according to claim 6, wherein a variable second voltage is applied onto the electroluminescent layer through the third electrode and the fourth electrode.

8. The light emitting diode chip structure according to claim 7, wherein the variable first voltage is converted into the variable second voltage through a variable resistor.

9. The light emitting diode chip structure according to claim 1, wherein the electroluminescent layer further covers the second semiconductor layer, the light emitting layer and the first semiconductor layer which are disposed on the side face of the mesa type light emitting diode structure.

10. A light emitting diode element, comprising:
a light emitting diode chip configured for emitting a first light with a light wavelength λ1; and
a wavelength transformation substance configured for transforming the first light with the light wavelength λ1 into a second light with a light wavelength λ2 after the wavelength transformation substance is irradiated by the first light with the light wavelength λ1,
wherein the light emitting diode chip comprises:
a substrate;
a mesa type light emitting diode structure formed on the substrate, comprising:
a first semiconductor layer disposed on the substrate;
a light emitting layer disposed on a portion of the first semiconductor layer, wherein a portion of the first semiconductor layer is uncovered; and
a second semiconductor layer disposed on the light emitting layer; and
a electroluminescent layer disposed on the second luminescent layer.

11. The light emitting diode element according to claim 10, wherein the light transmittance and the light reflectance of the electroluminescent layer are changed based on the change of the variable voltage applied onto the electroluminescent layer.

12. The light emitting diode element according to claim 11, wherein when the voltage applied onto the electroluminescent layer is gradually increased or decreased, the light transmittance is gradually decreased or increased, but the change of the light reflectance is contrary to that of the light transmittance.

13. The light emitting diode element according to claim 12, further comprising a first electrode and a second electrode, which are respectively disposed on the first semiconductor layer and the second semiconductor layer, so that the variable first voltage is applied between the first semiconductor layer and the second semiconductor layer through the first electrode and the second electrode.

14. The light emitting diode element according to claim 13, wherein since the electroluminescent layer is connected in series with the first semiconductor layer and the second semiconductor layer such that the variable first voltage is applied onto the electroluminescent layer.

15. The light emitting diode element according to claim 13, further comprising an insulating layer, wherein the insulating layer is located between the second semiconductor layer and the electroluminescent layer, and the light emitting diode chip structure further comprises a third electrode and a fourth electrode which are disposed on the electroluminescent layer.

16. The light emitting diode element according to claim 15, wherein a variable second voltage is applied onto the electroluminescent layer through the third electrode and the fourth electrode.

17. The light emitting diode element according to claim 16, wherein the variable first voltage is converted to the variable second voltage through a variable resistor.

18. The light emitting diode element according to any one of claims 10, wherein the first light with the light wavelength λ1 of the light emitting diode chip is within the wavelength range of ultraviolet light or visible light.

19. The light emitting diode element according to claim 18, wherein the wavelength transformation substance is selected from the group consisting of fluorescent powder, pigment, paint and a combination thereof.

20. The light emitting diode element according to claim 19, wherein the electroluminescent layer further covers the second semiconductor layer, the light emitting layer and the first semiconductor layer which are disposed on the side face of the mesa type light emitting diode structure.
